(19) United States
(12) Patent Application Publication
(10) Pub. No.: US 2025/0210580 A1
(43) Pub. Date: Jun. 26, 2025

(54) SEMICONDUCTOR PACKAGE

(71) Applicant: Samsung Electronics Co., Ltd., Suwon-si (KR)

(72) Inventors: Hee Woo AN, Suwon-si (KR); Bu-Won KIM, Suwon-si (KR)

(73) Assignee: Samsung Electronics Co., Ltd., Suwon-si (KR)

(21) Appl. No.: 18/916,896

(22) Filed: Oct. 16, 2024

(30) Foreign Application Priority Data
Dec. 22, 2023 (KR) 10-2023-0189851
Mar. 12, 2024 (KR) 10-2024-0034239

(51) Int. Cl. H01L 23/00; H01L 23/538; H01L 25/065; H01L 25/18; H10B 80/00

(52) U.S. Cl. CPC H01L 24/49; H01L 24/06; H01L 24/48; H01L 25/0657; H01L 23/538; H01L 25/18; H01L 2224/04042; H01L 2224/0603; H01L 2224/06177; H01L 2224/06515; H01L 2224/48145; H01L 2224/48227; H01L 2224/49112; H01L 2225/06506; H01L 2225/0651; H01L 2225/06562; H10B 80/00

(57) ABSTRACT

A semiconductor device includes a package substrate including substrate pads and a first, second, and third semiconductor chips sequentially stacked on the package substrate. The first semiconductor chip includes first signal pads and first dummy pads in a line, the second semiconductor chip includes second signal pads and third signal pads disposed in a line, the third semiconductor chip includes fourth signal pads disposed in a line. The first signal pads correspond to the second signal pads, the first dummy pads correspond to the third signal pads, the third signal pads correspond to the fourth signal pads, on a one-to-one basis.

### CROSS-REFERENCE TO RELATED APPLICATION

This application claims priority from Korean Patent Application No. 10-2023-0189851 filed on Dec. 22, 2023 and No. 10-2024-0034239 filed on Mar. 12, 2024 in the Korean Intellectual Property Office and all the benefits accruing therefrom under 35 U.S.C. 119, the contents of which in its entirety are herein incorporated by reference.

### BACKGROUND

### Technical Field

The present disclosure relates to a semiconductor packages.

### Description of the Related Art

With the recent trend of miniaturization and lightweight of electronic components, downsizing in a semiconductor package mounted on the electronic component is also required. An area of the package is limited, whereas the number and size of semiconductor chips in the package are increasing.

Therefore, it is necessary to efficiently place the semiconductor chips within the limited area of the package. To this end, a multi-chip type semiconductor package in which several chips are stacked to be implemented as a single package is advantageous.

The multi-chip type semiconductor package may electrically connect bonding pads of chips by using a bonding wire. Accordingly, in the multi-chip type semiconductor package, it is necessary to reduce a length of the bonding wire.

### BRIEF SUMMARY

Some example embodiments of the present disclosure are to provide semiconductor packages capable of reducing a length of a bonding wire electrically connecting chips.

According to an example embodiment of the present disclosure, a semiconductor package includes a package substrate including a plurality of substrate pads and a first semiconductor chip, a second semiconductor chip and a third semiconductor chip sequentially stacked on the package substrate, wherein the first semiconductor chip includes a plurality of first signal pads and a plurality of first dummy pads, the plurality of first signal pads and the plurality of first dummy pads being in a line, the second semiconductor chip includes a plurality of second signal pads and a plurality of third signal pads, the second signal pads and the plurality of third signal pads being in a line, the third semiconductor chip includes a plurality of fourth signal pads, the plurality of fourth signal pads being in a line, the plurality of first signal pads correspond to the plurality of second signal pads on a one-to-one basis, the plurality of first dummy pads correspond to the plurality of third signal pads on a one-to-one basis, and the plurality of third signal pads correspond to the plurality of fourth signal pads on a one-to-one basis, a plurality of first wires each connecting one of the plurality of substrate pads to a corresponding one of the plurality of first signal pads, a plurality of second wires each connecting one of the plurality of first signal pads to a corresponding one of the plurality of second signal pads, a plurality of third wire each connecting one of the plurality of substrate pads to the plurality of first dummy pads, a plurality of fourth wires each connecting one of the plurality of first dummy pads to a corresponding one of the plurality of third signal pads, and a plurality of fifth wires each connecting one of the plurality of third signal pads to a corresponding one of the plurality of fourth signal pads.

According to an example embodiment of the present disclosure, a semiconductor package includes a package substrate including a plurality of substrate pads, and a first semiconductor chip, a second semiconductor chip, a third semiconductor chip and a fourth semiconductor chip sequentially stacked on the package substrate, wherein the first semiconductor chip includes a plurality of first signal pads and a plurality of first dummy pads, the plurality of first signal pads and the plurality of first dummy pads being in a line, the second semiconductor chip includes a plurality of second signal pads and a plurality of second dummy pads, the plurality of first signal pads and the plurality of second dummy pads being in a line, the third semiconductor chip includes a plurality of third signal pads and a plurality of third dummy pads, the plurality of third signal pads and the plurality of third dummy pads being in a line, the fourth semiconductor chip includes a plurality of fourth signal pads and a plurality of fourth dummy pads, the plurality of fourth signal pads and the plurality of fourth dummy pads being in a line, the plurality of first signal pads correspond to the plurality of second signal pads on a one-to-one basis, the plurality of first dummy pads correspond to the plurality of second dummy pads on a one-to-one basis, the plurality of second dummy pads correspond to the plurality of third signal pads on a one-to-one basis, and the plurality of third signal pads correspond to the plurality of fourth signal pads on a one-to-one basis, a plurality of first wires each connecting one of the plurality of substrate pads to a corresponding one of the plurality of first signal pads, a plurality of third wires each connecting one of the plurality of substrate pads to a corresponding one of the plurality of first dummy pads, a plurality of third wires each connecting one of the plurality of substrate pads to a corresponding one of the plurality of first dummy pads, a plurality of fourth wires each connecting one of the plurality of first dummy pads to a corresponding one of the plurality of second dummy pads, a plurality of fifth wires each connecting one of the plurality of second dummy pads to a corresponding one of the plurality of third signal pads, and a plurality of sixth wires each connecting one of the plurality of third signal pads to a corresponding one of the plurality of fourth signal pads.

According to an example embodiment of the present disclosure, a semiconductor package includes a package substrate including a plurality of substrate pads, a first semiconductor chip, a second semiconductor chip and a third semiconductor chip sequentially stacked on the package substrate in a cascade type and a memory controller chip flip-chip bonded onto the package substrate and spaced apart from the first semiconductor chip, wherein the first semiconductor chip is a memory chip that is wire-bonded to the package substrate and includes a plurality of first signal pads and a plurality of first dummy pads, the plurality of first signal pads and the plurality of first dummy pads being in a line, the second semiconductor chip is a memory chip including a plurality of second signal pads and a plurality of third signal pads, the plurality of second signal pads and the plurality of third signal pads being in a line, the third semiconductor chip is a memory chip including a plurality of fourth signal pads, the plurality of fourth signal pads being in a line, the plurality of first signal pads correspond to the plurality of second signal pads on a one-to-one basis, the plurality of first dummy pads correspond to the plurality of third signal pads on a one-to-one basis, and the plurality of third signal pads correspond to the plurality of fourth signal pads on a one-to-one basis, a plurality of first wires each connecting one of the plurality of substrate pads with to a corresponding one of the plurality of first signal pads, a plurality of second wires each connecting one of the plurality of first signal pads to a corresponding one of the plurality of second signal pads, a plurality of third wires each connecting one of the plurality of substrate pads to a corresponding one of the plurality of first dummy pads, a plurality of fourth wires each connecting one of the plurality of first dummy pads to a corresponding one of the plurality of third signal pads, and a plurality of fifth wires each connecting one of the plurality of third signal pads to a corresponding one of the plurality of fourth signal pads.

However, aspects of the present disclosure are not restricted to those set forth herein. The above and other aspects of the present disclosure will become more apparent to one of ordinary skill in the art to which the present disclosure pertains by referencing the detailed description of the present disclosure given below

### BRIEF DESCRIPTION OF THE DRAWINGS

The above and other aspects and features of the present disclosure will become more apparent by describing in detail illustrative example embodiments thereof with reference to the attached drawings, in which:

FIG. 1 is a side view illustrating a semiconductor package according to an example embodiment of the present disclosure.

FIG. 2 is a plan view illustrating an area A of the semiconductor package of FIG. 1 according to an example embodiment of the present disclosure.

FIG. 3 is a plan view illustrating an area A of the semiconductor package of FIG. 1 according to an example embodiment of the present disclosure.

FIG. 4 is a plan view illustrating an area A of the semiconductor package of FIG. 1 according to an example embodiment of the present disclosure.

FIG. 5 is a plan view illustrating an area A of the semiconductor package of FIG. 1 according to an example embodiment of the present disclosure.

FIG. 6 is a side view illustrating a semiconductor package according to an example embodiment of the present disclosure.

FIG. 7 is a plan view illustrating an area B of the semiconductor package of FIG. 6 according to an example embodiment of the present disclosure.

FIG. 8 is a plan view illustrating an area B of the semiconductor package of FIG. 6 according to an example embodiment of the present disclosure.

FIG. 9 is a plan view illustrating an area B of the semiconductor package of FIG. 6 in according to an example embodiment of the present disclosure.

FIG. 10 is a plan view illustrating an area B of the semiconductor package of FIG. 6 according to an example embodiment of the present disclosure.

FIG. 11 is a plan view illustrating an area B of the semiconductor package of FIG. 6 according to an example embodiment of the present disclosure.

FIG. 12 is a plan view illustrating an area B of the semiconductor package of FIG. 6 according to an example embodiment of the present disclosure.

FIG. 13 is a plan view illustrating an area B of the semiconductor package of FIG. 6 according to an example embodiment of the present disclosure.

FIG. 14 is a plan view illustrating an area B of the semiconductor package of FIG. 6 according to an example embodiment of the present disclosure.

### DETAILED DESCRIPTION

In the present disclosure, it will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

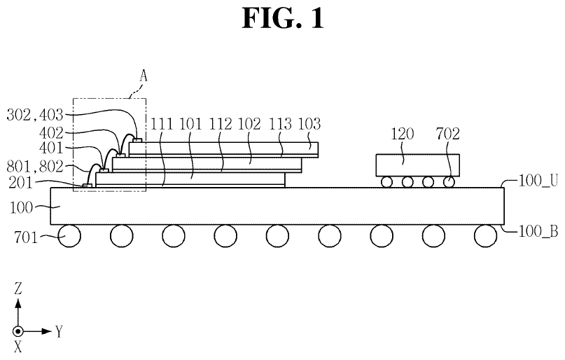

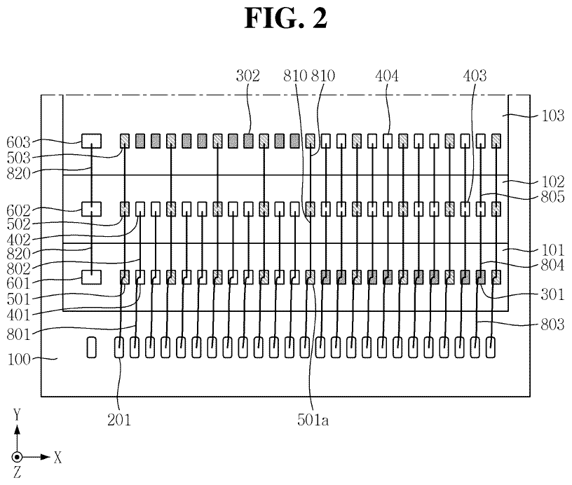

FIG. 1 is a side view illustrating a semiconductor package according to an example embodiment of the present disclosure. FIG. 2 is a plan view illustrating an area A of the semiconductor package of FIG. 1 according to an example embodiment of the present disclosure.

Referring to FIGS. 1 and 2, the semiconductor package may include a package substrate 100, a substrate pad 201, a first semiconductor chip 101, a second semiconductor chip 102, a third semiconductor chip 103, an external connection terminal 701, a logic chip 120 and a logic chip connection terminal 702.

The package substrate 100 may be a wiring structure for package. For example, the package substrate 100 may be a printed circuit board (PCB) or a ceramic wiring structure. In some example embodiments, the package substrate 100 may be a wiring structure for a wafer level package (WLP) fabricated at a wafer level. The package substrate 100 may include an upper surface 100_U and a lower surface 100_B, which are opposite to each other.

A plurality of substrate pads 201 may be disposed on the upper surface 100_U of the package substrate 100. The plurality of substrate pads 201 may be disposed to be spaced apart from each other in a first direction X. The plurality of substrate pads 201 may be disposed in a line in the first direction X on the upper surface 100_U of the package substrate 100. The substrate pad 201 may be used to electrically connect the package substrate 100 to other components. The substrate pad 201 may include, for example, a metallic material such as copper (Cu) and aluminum (Al), but is not limited thereto.

The first semiconductor chip 101 may be disposed on the upper surface 100_U of the package substrate 100. For example, the first semiconductor chip 101 may be wire-bonded to the package substrate 100. The first semiconductor chip 101 may be connected to the package substrate 100 through a first wire 801 and a third wire 803, which will be described later. The first semiconductor chip 101 may be, for example, a volatile memory chip such as a dynamic random access memory (DRAM) or a static RAM (SRAM).

A first adhesive portion 111 may be disposed on a surface of the first semiconductor chip 101, which is in contact with the package substrate 100. The first adhesive portion 111 may cover the surface of the first semiconductor chip 101, which is in contact with the package substrate 100. The first adhesive portion 111 may be disposed between the first semiconductor chip 101 and the package substrate 100. The first adhesive portion 111 may include a non-conductive film (NCF), a non-conductive paste (NCP), an insulating polymer or an epoxy resin, but the technical spirits of the present disclosure are not limited thereto. The first adhesive portion 111 may allow the first semiconductor chip 101 to be attached onto the package substrate 100.

The first semiconductor chip 101 may include a first option pad 601, a plurality of first power pads 501, a plurality of first signal pads 401 and a plurality of first dummy pads 301. The first option pad 601, the plurality of first power pads 501, the plurality of first signal pads 401 and the plurality of first dummy pads 301 may be disposed on the upper surface of the first semiconductor chip 101.

The first option pad 601, the plurality of first power pads 501, the plurality of first signal pads 401 and the plurality of first dummy pads 301 may be disposed to be spaced apart from each other on the upper surface of the first semiconductor chip 101. For example, the plurality of first power pads 501 and the plurality of first signal pads 401 may be disposed to be spaced apart from each other in the first direction X. The plurality of first power pads 501, the plurality of first signal pads 401 and the plurality of first dummy pads 301 may be disposed in a line in the first direction X on the first semiconductor chip 101.

The first option pad 601 may selectively operate the first signal pads 401 and the first dummy pads 301, which are disposed on the first semiconductor chip 101.

The first power pad 501 may provide a power or ground signal to the first semiconductor chip 101. The first power pad 501 may include a negative power supply (Vss) pad and a positive power supply (Vdd) pad. The negative power supply pad and the positive power supply pad may be alternately disposed.

For example, the plurality of first signal pads 401, which will be described later, may be disposed between the negative power supply pad and the positive power supply pad, which are alternately disposed. For another example, the plurality of first dummy pads 301, which will be described later, may be disposed between the negative power supply pad and the positive power supply pad, which are alternately disposed. For another example, the first signal pad 401 and the first dummy pad 301, which will be described later, may be disposed to be mixed between the negative power supply pad and the positive power supply pad, which are alternately disposed. For another example, the plurality of first signal pads 401 and the plurality of first dummy pads 301, which will be described later, may be disposed to be mixed between the negative power supply pad and the positive power supply pad, which are alternately disposed.

The first signal pad 401 may provide various signals, for example, data signals, etc., except for a ground pattern and a power pattern, which are related to a power source, to the first semiconductor chip 101. The first dummy pad 301 may not be electrically connected to the first semiconductor chip 101. In other words, the first dummy pad 301 may not provide a signal to the first semiconductor chip 101.

The first power pad 501, the first signal pad 401 and the first dummy pad 301 may include the same metal. For example, each of the first power pad 501, the first signal pad 401 and the first dummy pad 301 may include copper (Cu).

Among the first power pads 501, the first power pad 501 disposed at a position where the number of first power pads 501 disposed at one side is the same as the number of first power pads 501 disposed at the other side may be a reference power pad 501a. Based on the reference power pad 501a, the plurality of first signal pads 401 may be disposed at one side of the reference power pad 501a, and the plurality of first dummy pads 301 may be disposed at the other side thereof.

For example, the number of the plurality of first signal pads 401 disposed at one side of the reference power pad 501a may be the same as the number of the plurality of first dummy pads 301 disposed at the other side of the reference power pad 501a.

The second semiconductor chip 102 may be stacked on the first semiconductor chip 101. For example, the second semiconductor chip 102 may be wire-bonded onto the first semiconductor chip 101. The second semiconductor chip 102 may be connected to the first semiconductor chip 101 through a second wire 802 and a fourth wire 804, which will be described later. The second semiconductor chip 102 may be, for example, a volatile memory chip such as a dynamic random access memory (DRAM) or a static RAM (SRAM).

A second adhesive portion 112 may be disposed on a surface of the second semiconductor chip 102, which is in contact with the first semiconductor chip 101. The second adhesive portion 112 may cover the surface of the second semiconductor chip 102, which is in contact with the first semiconductor chip 101. The second adhesive portion 112 may be disposed between the first semiconductor chip 101 and the second semiconductor chip 102. The second adhesive portion 112 may include a non-conductive film (NCF), a non-conductive paste (NCP), an insulating polymer or an epoxy resin, but the technical spirits of the present disclosure are not limited thereto. The second adhesive portion 112 may allow the second semiconductor chip 102 to be attached onto the first semiconductor chip 101.

The second semiconductor chip 102 may include a second option pad 602, a plurality of second power pads 502, a plurality of second signal pads 402 and a plurality of third signal pads 403. The second option pad 602, the plurality of second power pads 502, the plurality of second signal pads 402 and the plurality of third signal pads 403 may be disposed on an upper surface of the second semiconductor chip 102.

The second option pad 602, the plurality of second power pads 502, the plurality of second signal pads 402 and the plurality of third signal pads 403 may be disposed to be spaced apart from one another on the upper surface of the second semiconductor chip 102. For example, the plurality of second power pads 502 and the plurality of second signal pads 402 may be disposed to be spaced apart from each other in the first direction X. The second option pad 602, the plurality of second power pads 502, the plurality of second signal pads 402 and the plurality of third signal pads 403 may be disposed in a line in the first direction X on the second semiconductor chip 102.

The second option pad 602 may selectively operate the second signal pad 402 and the third signal pad 403, which are disposed on the second semiconductor chip 102.

The second power pad 502 may provide a power or ground signal to the second semiconductor chip 102. The second power pad 502 may include a negative power supply (Vss) pad and a positive power supply (Vdd) pad. The negative power supply pad and the positive power supply pad may be alternately disposed.

For example, the plurality of second signal pads 402, which will be described later, may be disposed between the negative power supply pad and the positive power supply pad, which are alternately disposed. For another example, the plurality of third signal pads 403, which will be described later, may be disposed between the negative power supply pad and the positive power supply pad, which are alternately disposed. For another example, the second signal pad 402 and the third signal pad 403, which will be described later, may be disposed to be mixed between the negative power supply pad and the positive power supply pad, which are alternately disposed. For another example, the plurality of second signal pads 402 and the plurality of third signal pads 403, which will be described later, may be disposed to be mixed between the negative power supply pad and the positive power supply pad, which are alternately disposed.

The second signal pad 402 may provide various signals, for example, data signals, etc., except for a ground pattern and a power pattern, which are related to a power source, to the second semiconductor chip 102. The third signal pad 403 may provide various signals, for example, data signals, etc., except for a ground pattern and a power pattern, which are related to a power source, to the second semiconductor chip 102.

The second power pad 502, the second signal pad 402 and the third signal pad 403 may include the same metal. For example, each of the second power pad 502, the second signal pad 402 and the third signal pad 403 may include copper (Cu).

The third semiconductor chip 103 may be stacked on the second semiconductor chip 102. For example, the third semiconductor chip 103 may be wire-bonded onto the second semiconductor chip 102. The third semiconductor chip 103 may be connected to the second semiconductor chip 102 through a fifth wire 805 that will be described later. The third semiconductor chip 103 may be, for example, a volatile memory chip such as a dynamic random access memory (DRAM) or a static RAM (SRAM).

A third adhesive portion 113 may be disposed on a surface of the third semiconductor chip 103, which is in contact with the second semiconductor chip 102. The third adhesive portion 113 may cover the surface of the third semiconductor chip 103, which is in contact with the second semiconductor chip 102. The third adhesive portion 113 may be disposed between the second semiconductor chip 102 and the third semiconductor chip 103. The third adhesive portion 113 may include a non-conductive film (NCF), a non-conductive paste (NCP), an insulating polymer or an epoxy resin, but the technical spirits of the present disclosure are not limited thereto. The third adhesive portion 113 may allow the third semiconductor chip 103 to be attached onto the second semiconductor chip 102.

The third semiconductor chip 103 may include a third option pad 603, a plurality of third power pads 503, a plurality of second dummy pads 302 and a plurality of fourth signal pads 404. The third option pad 603, the plurality of third power pads 503, the plurality of second dummy pads 302 and the plurality of fourth signal pads 404 may be disposed on an upper surface of the third semiconductor chip 103.

The third option pad 603, the plurality of third power pads 503, the plurality of second dummy pads 302 and the plurality of fourth signal pads 404 may be disposed to be spaced apart from one another on the upper surface of the third semiconductor chip 103. For example, the plurality of third power pads 503 and the plurality of second dummy pads 302 may be disposed to be spaced apart from each other in the first direction X. The third option pad 603, the plurality of third power pads 503, the plurality of second dummy pads 302 and the plurality of fourth signal pads 404 may be disposed in a line in the first direction X on the third semiconductor chip 103.

The third option pad 603 may selectively operate the third signal pad 403 and the second dummy pad 302, which are disposed on the third semiconductor chip 103.

The third power pad 503 may provide a power or ground signal to the third semiconductor chip 103. The third power pad 503 may include a negative power supply (Vss) pad and a positive power supply (Vdd) pad. The negative power supply pad and the positive power supply pad may be alternately disposed.

For example, the plurality of fourth signal pads 404, which will be described later, may be disposed between the negative power supply pad and the positive power supply pad, which are alternately disposed. For another example, the plurality of second dummy pads 302, which will be described later, may be disposed between the negative power supply pad and the positive power supply pad, which are alternately disposed. For another example, the fourth signal pad 404 and the second dummy pad 302, which will be described later, may be disposed to be mixed between the negative power supply pad and the positive power supply pad, which are alternately disposed. For another example, the plurality of fourth signal pads 404 and the plurality of second dummy pads 302, which will be described later, may be disposed to be mixed between the negative power supply pad and the positive power supply pad, which are alternately disposed.

The fourth signal pad 404 may provide various signals, for example, data signals, etc., except for a ground pattern and a power pattern, which are related to a power source, to the third semiconductor chip 103. The second dummy pad 302 may not be electrically connected to the third semiconductor chip 103. In other words, the second dummy pad 302 may not provide a signal to the third semiconductor chip 103.

The third power pad 503, the second dummy pad 302 and the fourth signal pad 404 may include the same metal. For example, each of the third power pad 503, the second dummy pad 302 and the fourth signal pad 404 may include copper (Cu).

The first semiconductor chip 101, the second semiconductor chip 102 and the third semiconductor chip 103 may be stacked on the package substrate 100 in a cascade type of a stair shape. For example, the first semiconductor chip 101, the second semiconductor chip 102 and the third semiconductor chip 103 may be sequentially stacked in a stair shape that ascends in a second direction Y.

An external connection terminal 701 may be disposed on the lower surface 100_B of the package substrate 100. The external connection terminal 701 may electrically connect the package substrate 100 to external terminals. In other words, an electrical signal of an external device may be provided to the package substrate 100 by the external connection terminal 701, and an electrical signal of the package substrate 100 may be provided to the external device.

The external connection terminal 701 may include a solder ball or a solder bump. The external connection terminal 701 may be, for example, a spherical shape or an elliptical shape, but is not limited thereto. The number, interval, arrangement, shape and the like of the external connection terminals 701 are not limited to the shown examples, and may vary depending on design. The external connection terminal 701 may include, for example, tin (Sn), indium (In), bismuth (Bi), antimony (Sb), copper (Cu), silver (Ag), zinc (Zn), lead (Pb) or combination thereof, but is not limited thereto.

The first signal pad 401 disposed on the first semiconductor chip 101, the second signal pad 402 disposed on the second semiconductor chip 102, the third signal pad 403 disposed on the second semiconductor chip 102 and the fourth signal pad 404 disposed on the third semiconductor chip 103 may be data signal (DQ) terminals. The number of first signal pads 401 disposed on the first semiconductor chip 101 may be eight. The sum of the second signal pads 402 and the third signal pads 403, which are disposed on the second semiconductor chip 102, may be 16. For example, each of the second signal pads 402 and the third signal pads 403, which are disposed on the second semiconductor chip 102, may be eight. The number of fourth signal pads 404 disposed on the third semiconductor chip 103 may be eight.

The logic chip 120 may be disposed on the package substrate 100. For example, the logic chip 120 may be spaced apart from the first semiconductor chip 101, and may be disposed on the package substrate 100. For example, the logic chip 120 may be flip-chip bonded onto the package substrate 100. The logic chip 120 may be an application processor (AP) such as a central processing unit (CPU), a graphic processing unit (GPU), a field-programmable gate array (FPGA), a digital signal processor, an encryption processor, a microprocessor, a microcontroller or an application-specific IC (ASIC), but is not limited thereto.

The logic chip connection terminal 702 may be disposed between the logic chip 120 and the package substrate 100. The logic chip connection terminal 702 may electrically connect the logic chip 120 to the package substrate 100. The logic chip 120 may receive an electrical signal from the package substrate 100 through the logic chip connection terminal 702. The logic chip connection terminal 702 may include, for example, a solder ball or a solder bump.

The first signal pad 401 on the first semiconductor chip 101 may be electrically connected to the substrate pad 201 on the package substrate 100 through the first wire 801. In other words, the first wire 801 may electrically connect the first semiconductor chip 101 to the package substrate 100.

The second signal pad 402 on the second semiconductor chip 102 may be electrically connected to the first signal pad 401 on the first semiconductor chip 101 through the second wire 802. In other words, the second signal pad 402 may electrically connect the first semiconductor chip 101, the second semiconductor chip 102 and the package substrate 100. The first signal pad 401 may correspond to the second signal pad 402 on a one-to-one basis.

The first dummy pad 301 on the first semiconductor chip 101 may be connected to the substrate pad 201 on the package substrate 100 through the third wire 803. In other words, the first dummy pad 301 may electrically connect the second semiconductor chip 102, the third semiconductor chip 103 and the package substrate 100. The first dummy pad 301 may correspond to the third signal pad 403 on a one-to-one basis.

The first dummy pad 301 may not be electrically connected to the first semiconductor chip 101 but be electrically connected to the third signal pad 403 of the second semiconductor chip 102 and the fourth signal pad 404 of the third semiconductor chip 103. In other words, the first dummy pad 301 may serve as a passage for only transferring an electrical signal to the second semiconductor chip 102 and the third semiconductor chip 103.

The third signal pad 403 on the second semiconductor chip 102 may be connected to the first dummy pad 301 on the first semiconductor chip 101 through the fourth wire 804. In other words, the third signal pad 403 may electrically connect the second semiconductor chip 102, the third semiconductor chip 103 and the package substrate 100.

The fourth signal pad 404 on the third semiconductor chip 103 may be connected to the third signal pad 403 on the second semiconductor chip 102 through the fifth wire 805. In other words, the fourth signal pad 404 may electrically connect the second semiconductor chip 102, the third semiconductor chip 103 and the package substrate 100. The third signal pad 403 may correspond to the fourth signal pad 404 on a one-to-one basis.

Because the first dummy pad 301 serves as a passage for only transferring an electrical signal, a wire directly connecting the second semiconductor chip 102 with the package substrate 100 may not be needed. That is, the third signal pad 403 of the second semiconductor chip 102 may be connected to the package substrate 100 via the first dummy pad 301. Because the second semiconductor chip 102 and the third semiconductor chip 103 may be electrically connected to the package substrate 100 by the third wire 803, the fourth wire 804 and the fifth wire 805, a length of the bonding wire for connecting the package substrate 100 with the second semiconductor chip 102 and a length of the bonding wire for connecting the package substrate 100 with the third semiconductor chip 103 may be shortened.

As the length of the bonding wire becomes shorter, electrical characteristics of signals transferred among the first semiconductor chip 101, the second semiconductor chip 102 and the third semiconductor chip 103 may be improved. For example, a signal processing speed among the first semiconductor chip 101, the second semiconductor chip 102 and the third semiconductor chip 103 may be increased. Also, as the length of the bonding wire becomes shorter, the overall thickness of the semiconductor package may be reduced.

A plurality of power connection wires 810 may connect the substrate pad 201 on the package substrate 100 with the first power pad 501 on the first semiconductor chip 101. Furthermore, the plurality of power connection wires 810 may connect the first power pad 501 on the first semiconductor chip 101 with the second power pad 502 on the second semiconductor chip 102. Furthermore, the plurality of power connection wires 810 may connect the second power pad 502 on the second semiconductor chip 102 with the third power pad 503 on the third semiconductor chip 103.

The power connection wire 810 may connect the substrate pad 201 on the package substrate 100, the first power pad 501 on the first semiconductor chip 101, the second power pad 502 on the second semiconductor chip 102 and the third power pad 503 on the third semiconductor chip 103. The plurality of power connection wires 810 may provide the power signal or the ground signal, which is provided from the external connection terminal 701, to the first power pad 501, the second power pad 502 and the third power pad 503. In other words, the plurality of power connection wires 810 may provide the power signal or the ground signal, which is provided from the external connection terminal 701, to the first semiconductor chip 101, the second semiconductor chip 102 and the third semiconductor chip 103.

The option pad connection wire 820 may connect the first option pad 601 on the first semiconductor chip 101 with the second option pad 602 on the second semiconductor chip 102. Also, the option pad connection wire 820 may connect the second option pad 602 on the second semiconductor chip 102 with the third option pad 603 on the third semiconductor chip 103.

FIG. 2 illustrates that the first option pad 601 on the first semiconductor chip 101 is internally connected to the package substrate 100 (instead of being connected to the substrate pad 201 via a bonding wire), but the present disclosure is not limited thereto, and may vary depending on design. As another example, the option pad connection wire 820 may connect the first option pad 601 on the first semiconductor chip 101 with the substrate pad 201 on the package substrate 100.

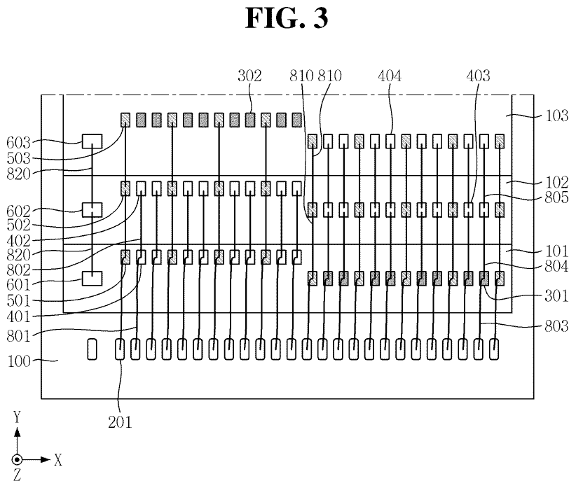

FIG. 3 is a plan view illustrating an area A of the semiconductor package of FIG. 1 according to an example embodiment of the present disclosure. For convenience of description, FIG. 3 will be mainly described based on differences from the description of FIGS. 1 and 2.

Referring to FIG. 3, the semiconductor package may include a package substrate 100, a substrate pad 201, a first semiconductor chip 101, a second semiconductor chip 102, a third semiconductor chip 103, an external connection terminal 701, a logic chip 120 and a logic chip connection terminal 702.

The first signal pad 401 on the first semiconductor chip 101 may be disposed so as not to overlap the first dummy pad 301 in the first direction X. The second signal pad 402 on the second semiconductor chip 102 may be disposed so as not to overlap the third signal pad 403 in the first direction X. The second dummy pad 302 on the third semiconductor chip 103 may be disposed so as not to overlap the fourth signal pad 404 in the first direction X.

Some of the plurality of first power pads 501 on the first semiconductor chip 101 may be disposed to overlap the first signal pad 401 in the first direction X, and the remaining first power pads 501 may be disposed to overlap the first dummy pad 301 in the first direction X.

Some of the plurality of second power pads 502 on the second semiconductor chip 102 may be disposed to overlap the second signal pad 402 in the first direction X, and the remaining second power pads 502 may be disposed to overlap the third signal pad 403 in the first direction X.

Some of the plurality of third power pads 503 on the third semiconductor chip 103 may be disposed to overlap the fourth signal pad 404 in the first direction X, and the remaining third power pads 503 may be disposed to overlap the second dummy pad 302 in the first direction X.

Although FIG. 3 illustrates that the first option pad 601 overlaps the first dummy pad 301 in the first direction X, the present disclosure is not limited thereto. As another example, the first option pad 601 may overlap the first signal pad 401 in the first direction X.

Although FIG. 3 illustrates that the second option pad 602 overlaps the third signal pad 403 in the first direction X, the present disclosure is not limited thereto. As another example, the second option pad 602 may overlap the second signal pad 402 in the first direction X.

Although FIG. 3 illustrates that the third option pad 603 overlaps the fourth signal pad 404 in the first direction X, the present disclosure is not limited thereto. As another example, the third option pad 603 may overlap the second dummy pad 302 in the first direction X.

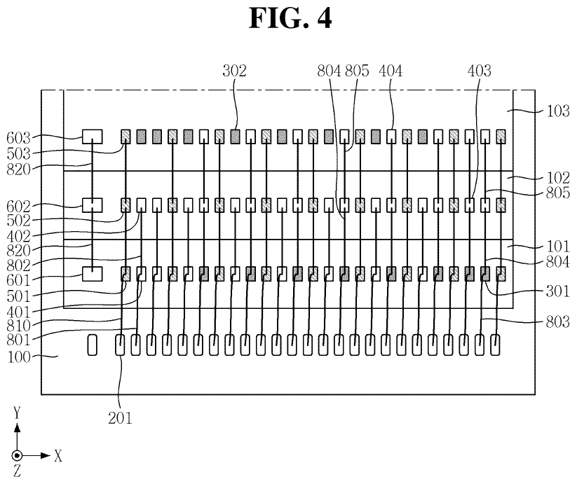

FIG. 4 is a plan view illustrating an area A of the semiconductor package of FIG. according to an example embodiment of the present disclosure. For convenience of description, FIG. 4 will be mainly described based on differences from the description of FIGS. 1 and 2.

Referring to FIG. 4, the semiconductor package may include a package substrate 100, a substrate pad 201, a first semiconductor chip 101, a second semiconductor chip 102, a third semiconductor chip 103, an external connection terminal 701, a logic chip 120 and a logic chip connection terminal 702.

The first signal pad 401 and the first dummy pad 301 on the first semiconductor chip 101 may not be continuously disposed. In other words, the first signal pad 401 and the first dummy pad 301 may be disposed without regularity.

The second signal pad 402 and the third signal pad 403 on the second semiconductor chip 102 may not be continuously disposed. In other words, the second signal pad 402 and the third signal pad 403 may be disposed without regularity.

The second dummy pad 302 and the fourth signal pad 404 on the third semiconductor chip 103 may not be continuously disposed. In other words, the second dummy pad 302 and the fourth signal pad 404 may be disposed without regularity.

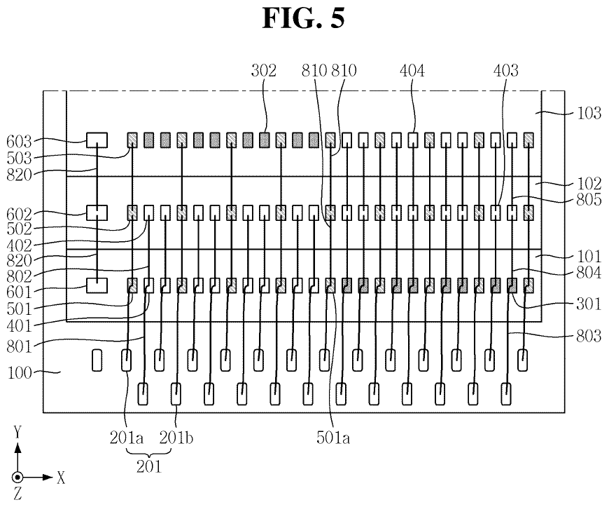

FIG. 5 is a plan view illustrating an area A of the semiconductor package of FIG. 1 according to an example embodiment of the present disclosure. For convenience of description, FIG. 5 will be mainly described based on differences from the description of FIGS. 1 and 2.

Referring to FIG. 5, the semiconductor package may include a package substrate 100, a substrate pad 201, a first semiconductor chip 101, a second semiconductor chip 102, a third semiconductor chip 103, an external connection terminal 701, a logic chip 120 and a logic chip connection terminal 702.

The substrate pad 201 on the package substrate 100 may include a first substrate pad 201a and a second substrate pad 201b. A plurality of first substrate pads 201a may be disposed in a line in the first direction X, and a plurality of second substrate pads 201b may be disposed in a line in the first direction X.

The plurality of first substrate pads 201a and the plurality of second substrate pads 202b may be disposed so as not to overlap each other in the first direction X. Therefore, the first wires 801 may have different lengths, and the third wires 803 may have different lengths.

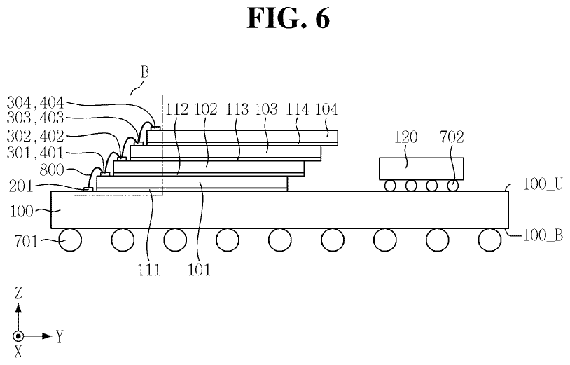

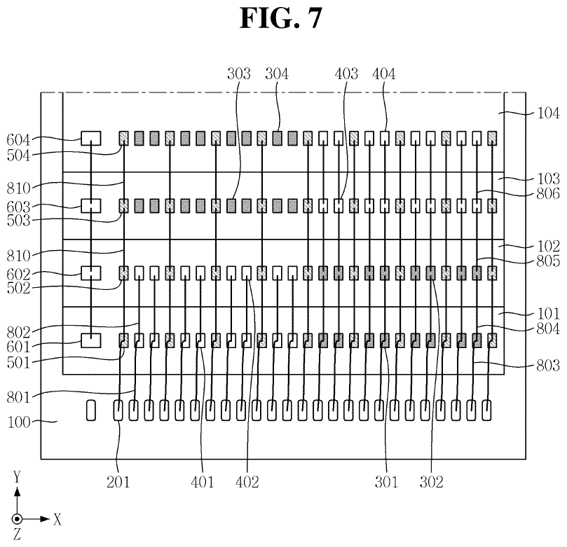

FIG. 6 is a side view illustrating a semiconductor package according to an example embodiment of the present disclosure. FIG. 7 is a plan view illustrating an area B of the semiconductor package of FIG. 6 according to an example embodiment of the present disclosure. For convenience of description, FIGS. 6 and 7 will be mainly described based on differences from the description of FIGS. 1 and 2.

Referring to FIGS. 6 and 7, the semiconductor package may include a package substrate 100, a substrate pad 201, a first semiconductor chip 101, a second semiconductor chip 102, a third semiconductor chip 103, a fourth semiconductor chip 104, an external connection terminal 701, a logic chip 120 and a logic chip connection terminal 702.

The second semiconductor chip 102 may be disposed on the upper surface 100_U of the first semiconductor chip 101. For example, the second semiconductor chip 102 may be wire-bonded onto the first semiconductor chip 101. The second semiconductor chip 102 may be connected to the first semiconductor chip 101, which is connected to the package substrate 100, through the second wire 802 and the fourth wire 804, which will be described later.

The second semiconductor chip 102 may include a second option pad 602, a plurality of second power pads 502, a second dummy pad 302 and a plurality of second signal pads 402. The second option pad 602, the plurality of second power pads 502, the second dummy pad 302 and the plurality of second signal pads 402 may be disposed on the upper surface of the second semiconductor chip 102.

The second option pad 602, the plurality of second power pads 502, the second dummy pad 302 and the plurality of second signal pads 402 may be disposed to be spaced apart from one another on the upper surface of the second semiconductor chip 102. For example, the plurality of second power pads 502 and the plurality of second signal pads 402 may be disposed to be spaced apart from each other in the first direction X. The second option pad 602, the plurality of second power pads 502, the second dummy pad 302 and the plurality of second signal pads 402 may be disposed in a line in the first direction on the second semiconductor chip 102.

For example, the plurality of second signal pads 402, which will be described later, may be disposed between the negative power supply pad and the positive power supply pad, which are alternately disposed. For another example, the plurality of second dummy pads 302, which will be described later, may be disposed between the negative power supply pad and the positive power supply pad, which are alternately disposed. For another example, the second signal pad 402 and the second dummy pad 302, which will be described later, may be disposed to be mixed between the negative power supply pad and the positive power supply pad, which are alternately disposed. For another example, the plurality of second signal pads 402 and the plurality of second dummy pads 302, which will be described later, may be disposed to be mixed between the negative power supply pad and the positive power supply pad, which are alternately disposed.

The second signal pad 402 may provide various signals, for example, data signals, etc., except for a ground pattern and a power pattern, which are related to a power source, to the second semiconductor chip 102. The second dummy pad 302 may not be electrically connected to the second semiconductor chip 102. In other words, the second dummy pad 302 may not provide a signal to the second semiconductor chip 102.

The second power pad 502, the second signal pad 402 and the second dummy pad 302 may include the same metal. For example, each of the second power pad 502, the second signal pad 402 and the second dummy pad 302 may include copper (Cu).

The third semiconductor chip 103 may be stacked on the second semiconductor chip 102. For example, the third semiconductor chip 103 may be wire-bonded onto the second semiconductor chip 102. The third semiconductor chip 103 may be connected to the second semiconductor chip 102 and the package substrate 100 through the fifth wire 805 that will be described later.

The third semiconductor chip 103 may include a third option pad 603, a plurality of third power pads 503, a plurality of third dummy pads 303 and a plurality of third signal pads 403. The third option pad 603, the plurality of third power pads 503, the plurality of third dummy pads 303 and the plurality of third signal pads 403 may be disposed on an upper surface of the third semiconductor chip 103.

The third option pad 603, the plurality of third power pads 503, the plurality of third dummy pads 303 and the plurality of third signal pads 403 may be disposed to be spaced apart from one another on the upper surface of the third semiconductor chip 103. For example, the plurality of third power pads 503 and the plurality of third signal pads 403 may be disposed to be spaced apart from each other in the first direction X. The third option pad 603, the plurality of third power pads 503, the plurality of third dummy pads 303 and the plurality of third signal pads 403 may be disposed in a line in the first direction X on the third semiconductor chip 103.

The plurality of third signal pads 403, which will be described later, may be disposed between the negative power supply pad and the positive power supply pad, which are alternately disposed. For another example, the third dummy pad 303, which will be described later, may be disposed between the negative power supply pad and the positive power supply pad alternately disposed. For another example, the third signal pad 403 and the third dummy pad 303, which will be described later, may be disposed to be mixed between the negative power supply pad and the positive power supply pad, which are alternately disposed. For another example, the third signal pad 403 and the plurality of third dummy pads 303, which will be described later, may be disposed to be mixed between the negative power supply pad and the positive power supply pad, which are alternately disposed.

The third signal pad 403 may provide various signals, for example, data signals, etc., except for a ground pattern and a power pattern related to power, to the third semiconductor chip 103. The third dummy pad 303 may not be electrically connected to the third semiconductor chip 103. In other words, the third dummy pad 303 may not provide a signal to the third semiconductor chip 103.

The third power pad 503, the third signal pad 403 and the third dummy pad 303 may include the same metal. For example, each of the third power pad 503, the third signal pad 403 and the third dummy pad 303 may include copper (Cu).

The fourth semiconductor chip 104 may be stacked on the third semiconductor chip 103. For example, the fourth semiconductor chip 104 may be wire-bonded onto the third semiconductor chip 103. The fourth semiconductor chip 104 may be connected to the third semiconductor chip 103 through the sixth wire 806 that will be described later. The fourth semiconductor chip 104 may be, for example, a volatile memory chip such as a dynamic random access memory (DRAM) or a static RAM (SRAM).

A fourth adhesive portion 114 may be disposed on a surface of the fourth semiconductor chip 104, which is in contact with the third semiconductor chip 103. The fourth adhesive portion 114 may cover the surface of the fourth semiconductor chip 104, which is in contact with the third semiconductor chip 103. The fourth adhesive portion 114 may be disposed between the third semiconductor chip 103 and the fourth semiconductor chip 104. The fourth adhesive portion 114 may include a non-conductive film (NCF), a non-conductive paste (NCP), an insulating polymer or an epoxy resin, but the technical spirits of the present disclosure are not limited thereto. The fourth adhesive portion 114 may allow the third semiconductor chip 103 to be attached onto the third semiconductor chip 103.

The fourth semiconductor chip 104 may include a fourth option pad 604, a plurality of fourth power pads 504, a plurality of fourth dummy pads 304 and a plurality of fourth signal pads 404. The fourth option pad 604, the plurality of fourth power pads 504, the plurality of fourth dummy pads 304 and the plurality of fourth signal pads 404 may be disposed on an upper surface of the fourth semiconductor chip 104.

The fourth option pad 604, the plurality of fourth power pads 504, the plurality of fourth dummy pads 304 and the plurality of fourth signal pads 404 may be disposed to be spaced apart from one another on the upper surface of the fourth semiconductor chip 104. For example, the plurality of fourth power pads 504 and the plurality of fourth signal pads 404 may be disposed to be spaced apart from each other in the first direction X. The fourth option pad 604, the plurality of fourth power pads 504, the plurality of fourth dummy pads 304 and the plurality of fourth signal pads 404 may be disposed in a line in the first direction X on the fourth semiconductor chip 104.

The fourth option pad 604 may selectively operate the fourth signal pad 404 and the fourth dummy pad 304, which are disposed on the fourth semiconductor chip 104.

The fourth power pad 504 may provide a power or ground signal to the fourth semiconductor chip 104. The fourth power pad 504 may include a negative power supply (Vss) pad and a positive power supply (Vdd) pad. The negative power supply pad and the positive power supply pad may be alternately disposed.

For example, the plurality of fourth signal pads 404, which will be described later, may be disposed between the negative power supply pad and the positive power supply pad, which are alternately disposed. For another example, the plurality of fourth dummy pads 304, which will be described later, may be disposed between the negative power supply pad and the positive power supply pad, which are alternately disposed. For another example, the fourth signal pad 404 and the fourth dummy pad 304, which will be described later, may be disposed to be mixed between the negative power supply pad and the positive power supply pad, which are alternately disposed.

The fourth signal pad 404 may provide various signals, for example, data signals, etc., except for a ground pattern and a power pattern, which are related to a power source, to the fourth semiconductor chip 104. The fourth dummy pad 304 may not be electrically connected to the fourth semiconductor chip 104. In other words, the fourth dummy pad 304 may not provide a signal to the fourth semiconductor chip 104.

The fourth power pad 504, the fourth signal pad 404 and the fourth dummy pad 304 may include the same metal. For example, each of the fourth power pad 504, the fourth signal pad 404 and the fourth dummy pad 304 may include copper (Cu).

The first semiconductor chip 101, the second semiconductor chip 102, the third semiconductor chip 103 and the fourth semiconductor chip 104 may be stacked on the package substrate 100 in a cascade type of a stair shape. For example, the first semiconductor chip 101, the second semiconductor chip 102, the third semiconductor chip 103 and the fourth semiconductor chip 104 may be sequentially stacked in a stair shape that ascends in the second direction Y.

The first signal pad 401 disposed on the first semiconductor chip 101, the second signal pad 402 disposed on the second semiconductor chip 102, the third signal pad 403 disposed on the third semiconductor chip and the fourth signal pad 404 disposed on the fourth semiconductor chip 104 may be data signal (DQ) terminals. Each of the number of first signal pads 401 disposed on the first semiconductor chip 101, the number of the second signal pads 402 disposed on the second semiconductor chip 102, the number of the third signal pads 403 disposed on the third semiconductor chip 103 and the number of the fourth signal pads 404 disposed on the fourth semiconductor chip 104 may be eight.

The first signal pad 401 on the first semiconductor chip 101 may be electrically connected to the substrate pad 201 on the package substrate 100 through the first wire 801. In other words, the first wire 801 may electrically connect the first semiconductor chip 101 with the package substrate 100.

The second signal pad 402 on the second semiconductor chip 102 may be electrically connected to the first signal pad 401 on the first semiconductor chip 101 through the second wire 802. In other words, the second signal pad 402 may be electrically connected to the first semiconductor chip 101, the second semiconductor chip 102 and the package substrate 100. The first signal pad 401 may correspond to the second signal pad 402 on a one-to-one basis.

The first dummy pad 301 on the first semiconductor chip 101 may be electrically connected to the substrate pad 201 on the package substrate 100 through the third wire 803. The first dummy pad 301 may correspond to the second dummy pad 302 on a one-to-one basis.

The first dummy pad 301 may not be electrically connected to the first semiconductor chip 101 but be electrically connected to the third signal pad 403 of the third semiconductor chip 103 and the fourth signal pad 404 of the fourth semiconductor chip 104. In other words, the first dummy pad 301 may serve as a passage for only transferring an electrical signal to the third semiconductor chip 103 and the fourth semiconductor chip 104.

The second dummy pad 302 on the second semiconductor chip 102 may be electrically connected to the first dummy pad 301 on the first semiconductor chip 101 through the fourth wire 804. The second dummy pad 302 may correspond to the first dummy pad 301 on a one-to-one basis.

The second dummy pad 302 may not be electrically connected to the second semiconductor chip 102 but be electrically connected to the third signal pad 403 of the third semiconductor chip 103 and the fourth signal pad 404 of the fourth semiconductor chip 104. In other words, the first dummy pad 301 may serve as a passage for only transferring an electrical signal to the third semiconductor chip 103 and the fourth semiconductor chip 104.

The third signal pad 403 on the third semiconductor chip 103 may be electrically connected to the second dummy pad 302 on the second semiconductor chip 102 through the fifth wire 805. In other words, the third signal pad 403 may be electrically connected to the third semiconductor chip 103, the fourth semiconductor chip 104 and the package substrate 100. The third signal pad 403 may correspond to the second dummy pad 302 on a one-to-one basis.

The third dummy pad 303 on the third semiconductor chip 103 may not be electrically connected by a bonding wire. In other words, the third dummy pad 303 may not be connected to the first semiconductor chip 101, the second semiconductor chip 102 and the fourth semiconductor chip 104.

The fourth signal pad 404 on the fourth semiconductor chip 104 may be electrically connected to the third signal pad 403 on the third semiconductor chip 103 through the sixth wire 806. In other words, the fourth signal pad 404 may be electrically connected to the third semiconductor chip 103, the fourth semiconductor chip 104 and the package substrate 100. The fourth signal pad 404 may correspond to the third signal pad 403 on a one-to-one basis.

The fourth dummy pad 304 on the fourth semiconductor chip 104 may not be electrically connected by a bonding wire. In other words, the fourth dummy pad 304 may not be connected to the first semiconductor chip 101, the second semiconductor chip 102 and the fourth semiconductor chip 104.

Because the first dummy pad 301 and the second dummy pad 302 serve as passages for only transferring an electrical signal, a wire directly connecting the third semiconductor chip 103 with the package substrate 100 may not be needed. That is, the third signal pad 403 of the third semiconductor chip 103 may be connected to the package substrate 100 via the second dummy pad 302 and the first dummy pad 301. Because the third semiconductor chip 103 and the fourth semiconductor chip 104 may be connected to the package substrate 100 by the third wire 803, the fourth wire 804, the fifth wire 805 and the sixth wire 806, a length of the bonding wire for connecting the package substrate 100 with the third semiconductor chip 103 may be shortened.

As the length of the bonding wire becomes shorter, electrical characteristics of signals transferred among the first semiconductor chip 101, the second semiconductor chip 102, the third semiconductor chip 103 and the fourth semiconductor chip 104 may be improved. For example, a signal processing speed among the first semiconductor chip 101, the second semiconductor chip 102, the third semiconductor chip 103 and the fourth semiconductor chip 104 may be increased. Also, as the length of the bonding wire becomes shorter, the overall thickness of the semiconductor package may be reduced.

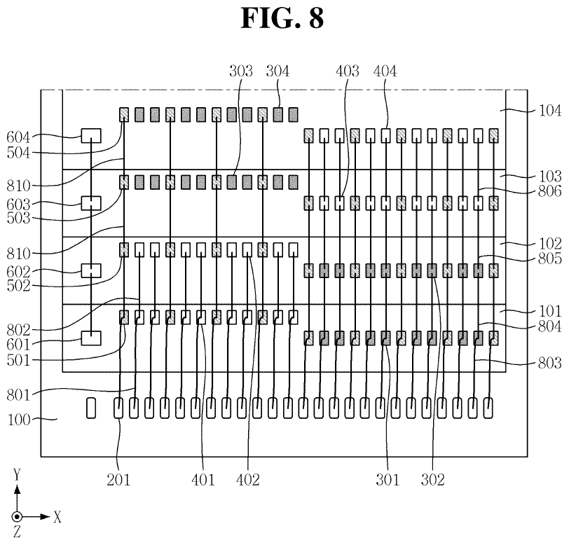

FIG. 8 is a plan view illustrating an area B of the semiconductor package of FIG. 6 according to an example embodiment of the present disclosure. For convenience of description, FIG. 8 will be mainly described based on differences from the description of FIGS. 6 and 7.

Referring to FIG. 8, the semiconductor package may include a package substrate 100, a substrate pad 201, a first semiconductor chip 101, a second semiconductor chip 102, a third semiconductor chip 103, a fourth semiconductor chip 104, an external connection terminal 701, a logic chip 120 and a logic chip connection terminal 702.

The first signal pad 401 on the first semiconductor chip 101 may be disposed so as not to overlap the first dummy pad 301 in the first direction X. The second signal pad 402 on the second semiconductor chip 102 may be disposed so as not to overlap the second dummy pad 302 in the first direction X. The third dummy pad 303 on the third semiconductor chip 103 may be disposed so as not to overlap the third signal pad 403 in the first direction X. The fourth dummy pad 304 on the fourth semiconductor chip 104 may be disposed so as not to overlap the fourth signal pad 404 in the first direction X.

Some of the plurality of first power pads 501 on the first semiconductor chip 101 may be disposed to overlap the first signal pad 401 in the first direction X, and the remaining first power pads 501 may be disposed to overlap the first dummy pad 301 in the first direction X.

Some of the plurality of second power pads 502 on the second semiconductor chip 102 may be disposed to overlap the second signal pad 402 in the first direction X, and the remaining second power pads 502 may be disposed to overlap the second dummy pad 302 in the first direction X.

Some of the plurality of third power pads 503 on the third semiconductor chip 103 may be disposed to overlap the third signal pad 403 in the first direction X, and the remaining third power pads 503 may be disposed to overlap the third dummy pad 303 in the first direction X.

Some of the plurality of fourth power pads 504 on the fourth semiconductor chip 104 may be disposed to overlap the fourth signal pad 404 in the first direction X, and the remaining fourth power pads 504 may be disposed to overlap the fourth dummy pad 304 in the first direction X.

Although FIG. 8 illustrates that the first option pad 601 overlaps the first dummy pad 301 in the first direction X, the present disclosure is not limited thereto. As another example, the first option pad 601 may overlap the first signal pad 401 in the first direction X.

Although FIG. 8 illustrates that the second option pad 602 overlaps the second dummy pad 302 in the first direction X, the present disclosure is not limited thereto. As another example, the second option pad 602 may overlap the second signal pad 402 in the first direction X.

Although FIG. 8 illustrates that the third option pad 603 overlaps the third signal pad 403 in the first direction X, the present disclosure is not limited thereto. As another example, the third option pad 603 may overlap the third dummy pad 303 in the first direction X.

Although FIG. 8 illustrates that the fourth option pad 604 overlaps the fourth signal pad 404 in the first direction X, the present disclosure is not limited thereto. As another example, the fourth option pad 604 may overlap the fourth dummy pad 304 in the first direction X.

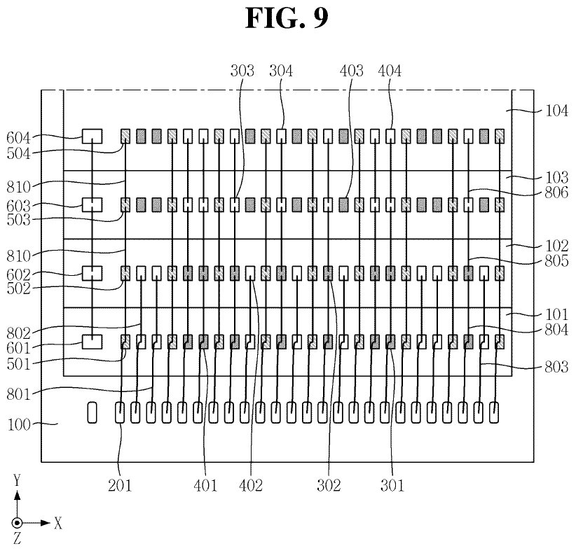

FIG. 9 is a plan view illustrating an area B of the semiconductor package of FIG. 6 according to an example embodiment of the present disclosure. For convenience of description, FIG. 9 will be mainly described based on differences from the description of FIGS. 6 and 7.

Referring to FIG. 9, the semiconductor package may include a package substrate 100, a substrate pad 201, a first semiconductor chip 101, a second semiconductor chip 102, a third semiconductor chip 103, a fourth semiconductor chip 104, an external connection terminal 701, a logic chip 120 and a logic chip connection terminal 702.

The first signal pad 401 and the first dummy pad 301 on the first semiconductor chip 101 may not be continuously disposed. In other words, the first signal pad 401 and the first dummy pad 301 may be disposed without regularity.

The second signal pad 402 and the second dummy pad 302 on the second semiconductor chip 102 may not be continuously disposed. In other words, the second signal pad 402 and the second dummy pad 302 may be disposed without regularity.

The third dummy pad 303 and the third signal pad 403 on the third semiconductor chip 103 may not be continuously disposed. In other words, the third dummy pad 303 and the third signal pad 403 may be disposed without regularity.

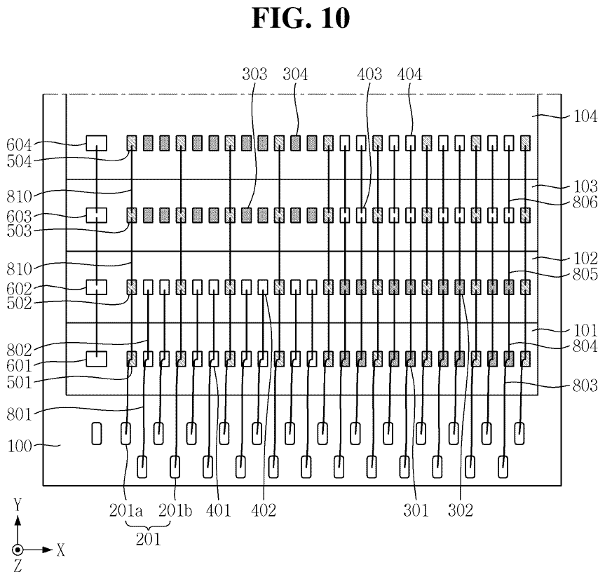

FIG. 10 is a plan view illustrating an area B of the semiconductor package of FIG. 6 according to another embodiment of the present disclosure. For convenience of description, FIG. 10 will be mainly described based on differences from the description of FIGS. 6 and 7.

Referring to FIG. 10, the semiconductor package may include a package substrate 100, a substrate pad 201, a first semiconductor chip 101, a second semiconductor chip 102, a third semiconductor chip 103, a fourth semiconductor chip 104, an external connection terminal 701, a logic chip 120 and a logic chip connection terminal 702.

The substrate pad 201 on the package substrate 100 may include a first substrate pad 201a and a second substrate pad 201b. A plurality of first substrate pads 201a may be disposed in a line in the first direction X, and a plurality of second substrate pads 201b may be disposed in a line in the first direction X.

The plurality of first substrate pads 201a and the plurality of second substrate pads 201b may be disposed so as not to overlap each other in the first direction X. Therefore, the first wires 801 may have different lengths, and the third wires 803 may have different lengths.

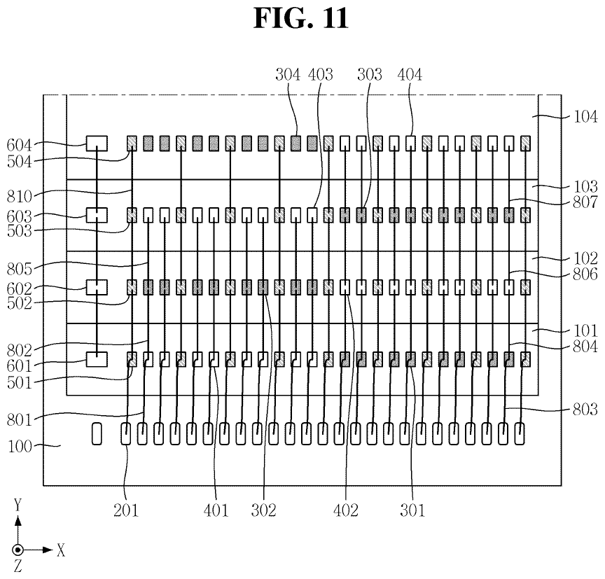

FIG. 11 is a plan view illustrating an area B of the semiconductor package of FIG. 6 according to an example embodiment of the present disclosure. For convenience of description, FIG. 11 will be mainly described based on differences from the description of FIGS. 6 and 7.

Referring to FIG. 11, the semiconductor package may include a package substrate 100, a substrate pad 201, a first semiconductor chip 101, a second semiconductor chip 102, a third semiconductor chip 103, a fourth semiconductor chip 104, an external connection terminal 701, a logic chip 120 and a logic chip connection terminal 702.

The third semiconductor chip 103 may be disposed on the second semiconductor chip 102. For example, the third semiconductor chip 103 may be wire-bonded onto the second semiconductor chip 102. The third semiconductor chip 103 may be connected to the first semiconductor chip 101 and the package substrate 100 through the third wire 803, the second wire 802 and the first wire 801, which will be described later.

The fourth semiconductor chip 104 may be stacked on the third semiconductor chip 103. For example, the fourth semiconductor chip 104 may be wire-bonded onto the third semiconductor chip 103. The fourth semiconductor chip 104 may be connected to the third semiconductor chip 103 through the seventh wire 807 that will be described later.

The third signal pad 403 on the third semiconductor chip 103 may be electrically connected to the second dummy pad 302 on the second semiconductor chip 102 through the fifth wire 805. In other words, the third signal pad 403 may be electrically connected to the third semiconductor chip 103, the first semiconductor chip 101 and the package substrate 100. The third signal pad 403 may correspond to the second dummy pad 302 on a one-to-one basis.

The third dummy pad 303 on the third semiconductor chip 103 may be connected to the second signal pad 402 on the second semiconductor chip 102 through the sixth wire 806. In other words, the third dummy pad 303 may be electrically connected to the second semiconductor chip 102, the fourth semiconductor chip 104 and the package substrate 100. The third dummy pad 303 may correspond to the second signal pad 402 on a one-to-one basis.

The third dummy pad 303 may not be electrically connected to the third semiconductor chip 103 but be electrically connected to the fourth signal pad 404 of the fourth semiconductor chip 104 and the second signal pad 402 of the second semiconductor chip 102. In other words, the third dummy pad 303 may serve as a passage for only transferring an electrical signal to the second semiconductor chip 102 and the fourth semiconductor chip 104.

The fourth signal pad 404 on the fourth semiconductor chip 104 may be connected to the third dummy pad 303 on the third semiconductor chip 103 through the seventh wire 807. In other words, the fourth signal pad 404 may be electrically connected to the fourth semiconductor chip 104, the second semiconductor chip 102 and the package substrate 100. The fourth signal pad 404 may correspond to the third dummy pad 303 on a one-to-one basis.

Because the first dummy pad 301 and the third dummy pad 303 serve as passages for only transferring an electrical signal, a wire directly connecting the second semiconductor chip 102 with the fourth semiconductor chip 104 may not be needed. That is, the second signal pad 402 of the second semiconductor chip 102 may be connected to the package substrate 100 via the first dummy pad 301. Also, the fourth signal pad 404 of the fourth semiconductor chip 104 may be connected to the package substrate 100 via the third dummy pad 303.

Because the second dummy pad 302 serves as a passage for only transferring an electrical signal, a wire directly connecting the first semiconductor chip 101 with the third semiconductor chip 103 may not be needed. That is, the third signal pad 403 of the third semiconductor chip 103 may be connected to the first semiconductor chip 101 and the package substrate 100 via the second dummy pad 302. Because the third semiconductor chip 103 may be electrically connected to the package substrate 100 by the first wire 801, the second wire 802 and the third wire 803, a length of the bonding wire for connecting the package substrate 100 with the third semiconductor chip 103 may be shortened.

As the length of the bonding wire becomes shorter, electrical characteristics of signals transferred among the first semiconductor chip 101, the second semiconductor chip 102, the third semiconductor chip 103 and the fourth semiconductor chip 104 may be improved. For example, a signal processing speed among the first semiconductor chip 101, the second semiconductor chip 102, the third semiconductor chip 103 and the fourth semiconductor chip 104 may be increased. Also, as the length of the bonding wire becomes shorter, the overall thickness of the semiconductor package may be reduced.

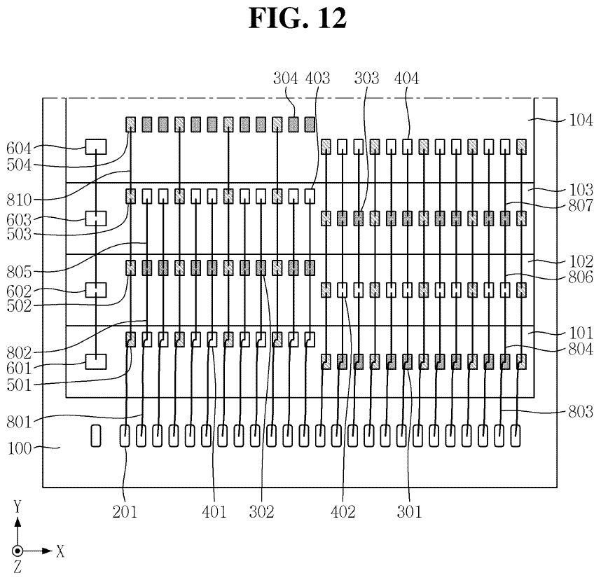

FIG. 12 is a plan view illustrating an area B of the semiconductor package of FIG. 6 in according to an example embodiment of the present disclosure. For convenience of description, FIG. 12 will be mainly described based on differences from the description of FIGS. 6 and 11.

Referring to FIG. 12, the semiconductor package may include a package substrate 100, a substrate pad 201, a first semiconductor chip 101, a second semiconductor chip 102, a third semiconductor chip 103, a fourth semiconductor chip 104, an external connection terminal 701, a logic chip 120 and a logic chip connection terminal 702.

The first signal pad 401 on the first semiconductor chip 101 may be disposed so as not to overlap the first dummy pad 301 in the first direction X. The second signal pad 402 on the second semiconductor chip 102 may be disposed so as not to overlap the second dummy pad 302 in the first direction X. The third dummy pad 303 on the third semiconductor chip 103 may be disposed so as not to overlap the third signal pad 403 in the first direction X. The fourth dummy pad 304 on the fourth semiconductor chip 104 may be disposed so as not to overlap the fourth signal pad 404 in the first direction X.

Some of the plurality of first power pads 501 on the first semiconductor chip 101 may be disposed to overlap the first signal pad 401 in the first direction X, and the remaining first power pads 501 may be disposed to overlap the first dummy pad 301 in the first direction X.

Some of the plurality of second power pads 502 on the second semiconductor chip 102 may be disposed to overlap the second signal pad 402 in the first direction X, and the remaining second power pads 502 may be disposed to overlap the second dummy pad 302 in the first direction X.

Some of the plurality of third power pads 503 on the third semiconductor chip 103 may be disposed to overlap the third signal pad 403 in the first direction X, and the remaining third power pads 503 may be disposed to overlap the third dummy pad 303 in the first direction X.

Some of the plurality of fourth power pads 504 on the fourth semiconductor chip 104 may be disposed to overlap the fourth signal pad 404 in the first direction X, and the remaining fourth power pads 504 may be disposed to overlap the fourth dummy pad 304 in the first direction X.

Although FIG. 12 illustrates that the first option pad 601 overlaps the first dummy pad 301 in the first direction X, the present disclosure is not limited thereto. As another example, the first option pad 601 may overlap the first signal pad 401 in the first direction X.

Although FIG. 12 illustrates that the second option pad 602 overlaps the second signal pad 402 in the first direction X, the present disclosure is not limited thereto. As another example, the second option pad 602 may overlap the second dummy pad 302 in the first direction X.

Although FIG. 12 illustrates that the third option pad 603 overlaps the third dummy pad 303 in the first direction X, the present disclosure is not limited thereto. As another example, the third option pad 603 may overlap the third signal pad 403 in the first direction X.

Although FIG. 12 illustrates that the fourth option pad 604 overlaps the fourth signal pad 404 in the first direction X, the present disclosure is not limited thereto. As another example, the fourth option pad 604 may overlap the fourth dummy pad 304 in the first direction X.

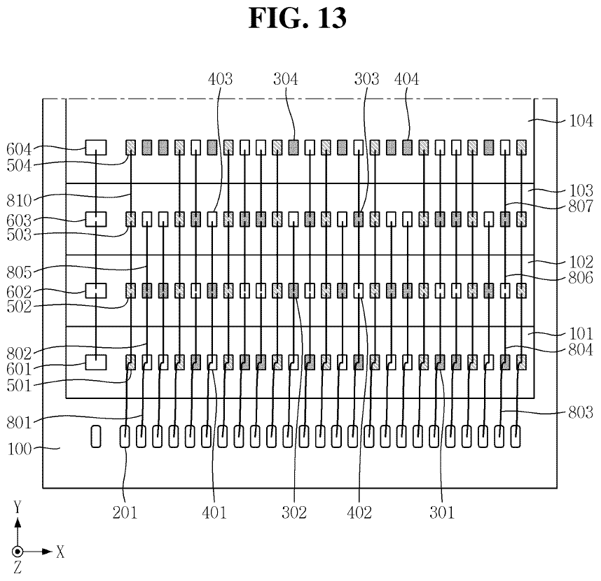

FIG. 13 is a plan view illustrating an area B of the semiconductor package of FIG. 6 according to another embodiment of the present disclosure. For convenience of description, FIG. 13 will be mainly described based on differences from the description of FIGS. 6 and 11.

Referring to FIG. 13, the semiconductor package may include a package substrate 100, a substrate pad 201, a first semiconductor chip 101, a second semiconductor chip 102, a third semiconductor chip 103, a fourth semiconductor chip 104, an external connection terminal 701, a logic chip 120 and a logic chip connection terminal 702.

The first signal pad 401 and the first dummy pad 301 on the first semiconductor chip 101 may not be continuously disposed. In other words, the first signal pad 401 and the first dummy pad 301 may be disposed without regularity.

The second signal pad 402 and the second dummy pad 302 on the second semiconductor chip 102 may not be continuously disposed. In other words, the second signal pad 402 and the second dummy pad 302 may be disposed without regularity.

The third dummy pad 303 and the third signal pad 403 on the third semiconductor chip 103 may not be continuously disposed. In other words, the third dummy pad 303 and the third signal pad 403 may be disposed without regularity.

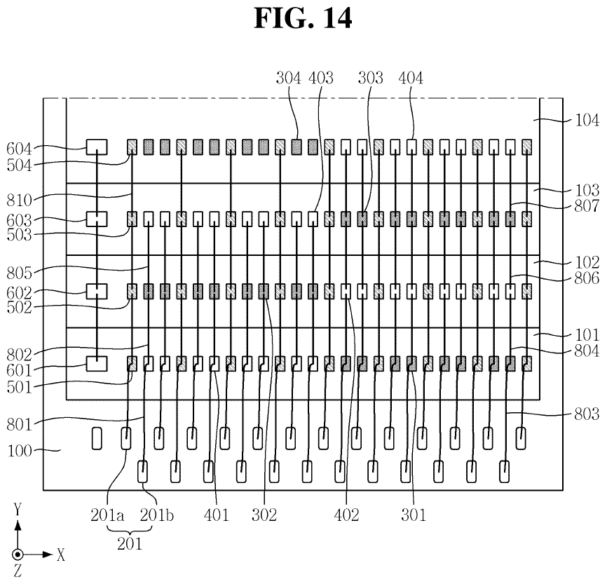

FIG. 14 is a plan view illustrating an area B of the semiconductor package of FIG. 6 according to an example embodiment of the present disclosure. For convenience of description, FIG. 14 will be mainly described based on differences from the description of FIGS. 6 and 11.

Referring to FIG. 14, the semiconductor package may include a package substrate 100, a substrate pad 201, a first semiconductor chip 101, a second semiconductor chip 102, a third semiconductor chip 103, a fourth semiconductor chip 104, an external connection terminal 701, a logic chip 120 and a logic chip connection terminal 702.

The substrate pad 201 on the package substrate 100 may include a first substrate pad 201a and a second substrate pad 201b. A plurality of first substrate pads 201a may be disposed in a line in the first direction X, and a plurality of second substrate pads 201b may be disposed in a line in the first direction X.

The plurality of first substrate pads 201a and the plurality of second substrate pads 201b may be disposed so as not to overlap each other in the first direction X. Therefore, the first wires 801 may have different lengths, and the third wires 803 may have different lengths.

In concluding the detailed description, those skilled in the art will appreciate that many variations and modifications may be made to the disclosed example embodiments without substantially departing from the principles of the present inventive concepts. Therefore, the disclosed example embodiments of the disclosure are used in a generic and descriptive sense only and not for purposes of limitation.

What is claimed is:

1. A semiconductor package comprising:
a package substrate including a plurality of substrate pads;
a first semiconductor chip, a second semiconductor chip and a third semiconductor chip sequentially stacked on the package substrate, wherein
the first semiconductor chip includes a plurality of first signal pads and a plurality of first dummy pads, the plurality of first signal pads and the plurality of first dummy pads being in a line,
the second semiconductor chip includes a plurality of second signal pads and a plurality of third signal pads, the second signal pads and the plurality of third signal pads being in a line,
the third semiconductor chip includes a plurality of fourth signal pads, the plurality of fourth signal pads being in a line,
the plurality of first signal pads correspond to the plurality of second signal pads on a one-to-one basis,
the plurality of first dummy pads correspond to the plurality of third signal pads on a one-to-one basis, and
the plurality of third signal pads correspond to the plurality of fourth signal pads on a one-to-one basis;
a plurality of first wires each connecting one of the plurality of substrate pads to a corresponding one of the plurality of first signal pads;
a plurality of second wires each connecting one of the plurality of first signal pads to a corresponding one of the plurality of second signal pads;
a plurality of third wire each connecting one of the plurality of substrate pads to the plurality of first dummy pads;
a plurality of fourth wires each connecting one of the plurality of first dummy pads to a corresponding one of the plurality of third signal pads; and
a plurality of fifth wires each connecting one of the plurality of third signal pads to a corresponding one of the plurality of fourth signal pads.

2. The semiconductor package of claim 1, further comprising:
a logic chip spaced apart from the first semiconductor chip on the package substrate.

3. The semiconductor package of claim 2, wherein the logic chip is flip-chip bonded onto the package substrate.

4. The semiconductor package of claim 1, further comprising:
an external connection terminal on a surface of the package substrate, on which the first semiconductor chip is not stacked.

5. The semiconductor package of claim 1, wherein the first semiconductor chip is wire-bonded to the package substrate.

6. The semiconductor package of claim 1, wherein
the first semiconductor chip further includes a first option pad, the first option pad being in a line with the plurality of first signal pads and the plurality of first dummy pads,
the second semiconductor chip further includes a second option pad, the second option pad being in a line with the plurality of second signal pads and the plurality of third signal pads, and
the third semiconductor chip further includes a third option pad, the third option pad being in a line with the plurality of fourth signal pads.

7. The semiconductor package of claim 1, wherein
the first semiconductor chip further includes a plurality of first power pads, the plurality of first power pads being in a line with the plurality of first signal pads and the plurality of first dummy pads,
the second semiconductor chip further includes a plurality of second power pads, the plurality of second power pads being in a line with the plurality of second signal pads and the plurality of third signal pads, and
the third semiconductor chip further includes a plurality of third power pads, the plurality of third power pads being in a line with the plurality of fourth signal pads.

8. The semiconductor package of claim 7, wherein
the plurality of first power pads include one or more negative power supply (Vss) pads and one or more positive power supply (Vdd) pads, and
a total of two of the plurality of first signal pads or a total of two of the plurality of first dummy pads are between one of the negative power supply pads and an adjacent one of the positive power supply pads.

9. The semiconductor package of claim 1, wherein the first semiconductor chip, the second semiconductor chip and the third semiconductor chip are stacked in a stair shape.

10. The semiconductor package of claim 1, wherein
a number of the first signal pads is 8,
a number of the fourth signal pads is 8, and
a sum of a number of the second signal pads and a number of the third signal pads is 16.

11. The semiconductor package of claim 1, wherein
the first semiconductor chip further includes a plurality of first power pads disposed in a line with the plurality of first signal pads and the plurality of first dummy pads, and
the plurality of first signal pads are at one side of a reference power pad, and the plurality of first dummy pads are at the other side of the reference power pad, the reference power pad being a first power pad of the plurality of first power pads at to which a number of the plurality of first power pads on one side of the first power pad is same as a number of the plurality of first power pads on the other side of the first power pad.

12. The semiconductor package of claim 1, wherein the first semiconductor chip, the second semiconductor chip and the third semiconductor chip are memory semiconductor chips.

13. The semiconductor package of claim 1, wherein the plurality of first signal pads, the plurality of second signal pads, the plurality of third signal pads and the plurality of fourth signal pads are data signal pads.

14. The semiconductor package of claim 1, wherein
the plurality of substrate pads include a plurality of first substrate pads and a plurality of second substrate pads,
the plurality of first substrate pads are in a line in a first direction,
the plurality of second substrate pads are in a line in the first direction, and
the plurality of first substrate pads and the plurality of second substrate pads do not to overlap each other in the first direction.

15. The semiconductor package of claim 14, wherein the plurality of first substrate pads and the plurality of second substrate pads are alternately disposed in the first direction.

16. A semiconductor package comprising:
a package substrate including a plurality of substrate pads;
a first semiconductor chip, a second semiconductor chip, a third semiconductor chip and a fourth semiconductor chip sequentially stacked on the package substrate, wherein
the first semiconductor chip includes a plurality of first signal pads and a plurality of first dummy pads, the plurality of first signal pads and the plurality of first dummy pads being in a line,
the second semiconductor chip includes a plurality of second signal pads and a plurality of second dummy pads, the plurality of first signal pads and the plurality of second dummy pads being in a line,
the third semiconductor chip includes a plurality of third signal pads and a plurality of third dummy pads, the plurality of third signal pads and the plurality of third dummy pads being in a line,
the fourth semiconductor chip includes a plurality of fourth signal pads and a plurality of fourth dummy pads, the plurality of fourth signal pads and the plurality of fourth dummy pads being in a line,
the plurality of first signal pads correspond to the plurality of second signal pads on a one-to-one basis,
the plurality of first dummy pads correspond to the plurality of second dummy pads on a one-to-one basis,
the plurality of second dummy pads correspond to the plurality of third signal pads on a one-to-one basis, and
the plurality of third signal pads correspond to the plurality of fourth signal pads on a one-to-one basis;
a plurality of first wires each connecting one of the plurality of substrate pads to a corresponding one of the plurality of first signal pads;
a plurality of second wires each connecting one of the plurality of first signal pads to a corresponding one of the plurality of second signal pads;
a plurality of third wires each connecting one of the plurality of substrate pads to a corresponding one of the plurality of first dummy pads;
a plurality of fourth wires each connecting one of the plurality of first dummy pads to a corresponding one of the plurality of second dummy pads;
a plurality of fifth wires each connecting one of the plurality of second dummy pads to a corresponding one of the plurality of third signal pads; and
a plurality of sixth wires each connecting one of the plurality of third signal pads to a corresponding one of the plurality of fourth signal pads.

17. The semiconductor package of claim 16, wherein the first semiconductor chip, the second semiconductor chip, the third semiconductor chip and the fourth semiconductor chip are stacked in a stair shape.

18. The semiconductor package of claim 16, wherein a number of the first signal pads, a number of the second signal pads, a number of the third signal pads and a number of the fourth signal pads are 8, respectively.

19. The semiconductor package of claim 16, wherein the first semiconductor chip, the second semiconductor chip, the third semiconductor chip and the fourth semiconductor chip are memory semiconductor chips.

20. A semiconductor package comprising:
a package substrate including a plurality of substrate pads;
a first semiconductor chip, a second semiconductor chip and a third semiconductor chip sequentially stacked on the package substrate in a cascade type;
a memory controller chip flip-chip bonded onto the package substrate and spaced apart from the first semiconductor chip, wherein
the first semiconductor chip is a memory chip that is wire-bonded to the package substrate and includes a plurality of first signal pads and a plurality of first dummy pads, the plurality of first signal pads and the plurality of first dummy pads being in a line,
the second semiconductor chip is a memory chip including a plurality of second signal pads and a plurality of third signal pads, the plurality of second signal pads and the plurality of third signal pads being in a line,
the third semiconductor chip is a memory chip including a plurality of fourth signal pads, the plurality of fourth signal pads being in a line,
the plurality of first signal pads correspond to the plurality of second signal pads on a one-to-one basis,
the plurality of first dummy pads correspond to the plurality of third signal pads on a one-to-one basis,
the plurality of third signal pads correspond to the plurality of fourth signal pads on a one-to-one basis,
a plurality of first wires each connecting one of the plurality of substrate pads with to a corresponding one of the plurality of first signal pads;
a plurality of second wires each connecting one of the plurality of first signal pads to a corresponding one of the plurality of second signal pads;
a plurality of third wires each connecting one of the plurality of substrate pads to a corresponding one of the plurality of first dummy pads;
a plurality of fourth wires each connecting one of the plurality of first dummy pads to a corresponding one of the plurality of third signal pads; and
a plurality of fifth wires each connecting one of the plurality of third signal pads to a corresponding one of the plurality of fourth signal pads.
